(19) United States
(12) Patent Application Publication
(10) Pub. No.: US 2025/0013823 A1
(43) Pub. Date: Jan. 9, 2025

(54) ADJUSTMENT OF FPGA SYSTEM DESIGN USING LANGUAGE-BASED MACHINE LEARNING MODELS

(71) Applicant: Altera Corporation, San Jose, CA (US)

(72) Inventors: Kuan Woei Lam, Bayan Lepas (MY); Chew Yee Kee, Bayan Lepas (MY); Zhi Chuan Yip, Ipoh (MY)

(21) Appl. No.: 18/896,267

(22) Filed: Sep. 25, 2024

(51) Int. Cl. G06F 40/274; G06F 30/33

(52) U.S. Cl. CPC G06F 40/274; G06F 30/33

(57) ABSTRACT

Systems or methods of the present disclosure may provide systems and methods for adjusting a system design for a field-programmable gate array (FPGA) in response to a compilation error based on one or more language-based machine learning (ML) models trained on error messages of prior system designs. A method may include receiving an error message associated with a system design of an FPGA, generating a language-based machine learning (ML) prompt based at least on the error message, and determining an adjustment to the system design based on providing the language-based ML prompt to one or more language-based ML models trained on prior error messages.

### BACKGROUND

The present disclosure relates generally to integrated circuits, such as processors and/or field-programmable gate arrays (FPGAs). More particularly, the present disclosure relates to resolving errors that arise during compilation of system designs for FPGAs.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Programmable logic devices, a class of integrated circuits, may be programmed to perform a wide variety of operations. In certain instances, programming and compiling the programmable logic device with a high level design (HLD) may take long periods of time, such as over multiple hours or days. For example, the programmable logic devices may be fine-grained to compile register transfer level (RTL) based designs. The design may be decomposed into millions of primitives to be implemented onto the fine-grained programmable device, thereby causing a relatively long compile time (e.g., hours or days). The long compilation time may hinder market traction. For example, the long compilation time may increase both development cost and development time, thereby reducing adoption of programmable logic devices by users. Indeed, compilation time for programmable logic devices may be computationally intensive, resource intensive, and cost intensive due to the fine-grained nature of the programmable logic device. Moreover, when an error arises during compilation, it may be difficult for a designer or operator to interpret or resolve the error.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device, in accordance with an embodiment of the present disclosure;

FIG. 2 is a block diagram of a data processing system including components of the system of FIG. 1, in accordance with an embodiment of the present disclosure;

FIG. 3 is a flow chart of a method for adjusting a system design based on one or more language-based ML models in response to a compilation error that may be performed by the data processing system of FIG. 2, in accordance with an embodiment of the present disclosure;

FIG. 4 is an illustration of an example language-based ML prompt that may be generated as part of the method of FIG. 3, in accordance with an embodiment of the present disclosure;

FIG. 5 is an illustration of an example user interface that includes indications of compilation error messages, generating language-based ML prompts, and determining adjustments to a system design, in accordance with an embodiment of the present disclosure; and

FIG. 6 is an illustration of example training data that may be used to train one or more language-based ML models used to adjust a system design, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As mentioned, programming and compiling a programmable logic device with a system design (e.g., a high-level design (HLD)) may take long periods of time, such as over multiple hours or days. The long compilation may increase both development cost and development time, thereby reducing adoption of programmable logic devices by users. Indeed, compilation time for programmable logic devices may be computationally intensive, resource intensive, and cost intensive due to the fine-grained nature of the programmable logic device. This may be especially troublesome when compilation is an integral part of the system design process. For example, a system design may be repeatedly compiled with various parameters, approaches, devices, and the like to determine an optimal system design with suitable devices, but this iterative process may be encumbered by long compilation times.

Further, compilation of a system design for an FPGA may be unsuccessful due to, for example, syntax errors, resource constraints, clocking issues, design rule violations, timing violations, or other aspects of the system design. The compiler may reference various rules, system requirements, and the like to identify an error in a system design, and may report the error such that the system design may be adjusted accordingly. However, compilation error reports may be difficult to understand and may lack an indication of procedures that may fix the compilation error. It may be desirable for a system design to be automatically adjusted based on an error report such that a system design may be adjusted and compiled more efficiently.

The present systems and techniques relate to embodiments for adjusting a system design for an FPGA in response to a compilation error based on one or more language-based machine learning (ML) models trained on prior compilation error messages. An error response component may receive a compilation error message resulting from a compilation attempt of a system design. The error response component may map the compilation error message to one or more portions of design software responsible for producing the compilation error. For example, the design software may include legality code or compiler software used by a compiler to determine whether a system design would function properly on a device. The design software may include rules and constraints for resources, connections, timings, and so on of the device. After mapping the compilation error message to the one or more portions of the design software responsible for producing the compilation error, the error response component may determine one or more agents that correspond to the one or more portions. As such, the error response component may determine the one or more agents responsible for generating the compilation error message. As used herein, agents may be understood to include subsystems, parameters, commands, or other aspects of a system design that identify and report a compilation error.

The error response component may then generate a language-based ML model prompt to be provided to one or more language-based ML models. As described herein, the language-based ML model prompt may include a code portion of the compilation error message, along with a natural language prompt. The natural language prompt may include one or more agents determined to be responsible for the compilation error message and a natural language indication of a desired output, as examples. In some embodiments, the prompt may include the one or more agents as listings of potential agents from which the language-based ML model may select as identified agents. The potential agents may include commands (e.g., add, delete, modify), subsystems and/or values (e.g., port, parameter), identifiers (e.g., port name, parameter name), or other aspects of a system design. The indication of the desired output may take a natural language form, such as “what is the expected value/connectivity”.

The one or more language-based ML models may include one or more large language models (LLMs) or other suitable language-based ML models. Further, the one or more language-based ML models may be trained on numerous (e.g., hundreds of, thousands of, millions of, billions of) error messages of prior system designs to produce a language-based ML output that addresses the compilation error. That is, the one or more ML models may be fine-tuned to address compilation errors. The error messages of prior system designs may include error messages (e.g., compilation error messages) occurring in any suitable previously-compiled system designs, potential agents of error messages, identified agents output by one or more ML models, and/or adjustments to prior system designs based on identified agents. The prior system designs may or may not have a direct relationship to the system design of the compilation error message received by the error response component. For example, the error messages of the prior system designs may be from actual system designs developed by a first-party manufacturer of the FPGA, a first-party manufacturer of the design software, or a third-party developer different from the first party-manufacturer of the design software. Additionally or alternatively, the error messages may include synthetic data from arbitrary system design code generated for training purposes, such as system design code produced by machine learning systems such as the one or more language-based ML models. Further, in some embodiments, the language-based ML output may be arranged in a form readable (e.g., as input) to a script of the design software, and the script may adjust the system design based on the language-based ML output.

In an example, the language-based ML output identifies agents from the one or more agents of the language-based ML model prompt that may be adjusted to resolve the compilation error. In some cases, the identified agents may be included as part of the one or more agents of the language-based ML model prompt. For example, if the language-based ML model prompt includes “add,” “delete,” and “modify,” as the one or more agents, the one or more language-based ML models may, based on the code portion of the compilation error message and the one or more agents, produce a language-based ML output that includes “modify” and omits “add” and “delete.” As such, the one or more language-based ML models may generate an output that indicates a “selection” between the one or more agents of the language-based ML model prompt.

Based on the language-based ML output, the error response component may adjust the system design to generate an adjusted system design. This may include adjusting parameters, connections, identifiers, or other aspects of the system design. In some examples, a data processing system may compile the adjusted system design. If the compilation is successful, the data processing system may produce an indication of the successful compilation and/or may transmit the compiled system design to a connected device. If, however, the compilation is unsuccessful, the data processing system may generate an additional compilation error message, and the error response component may generate an additional language-based ML model prompt based on the compilation error message and adjust the system design again based on providing the language-based ML model prompt to the one or more language-based ML models. In some examples, the error response component may continue to adjust the system design as such until compilation succeeds and/or until a threshold number of compilations is reached.

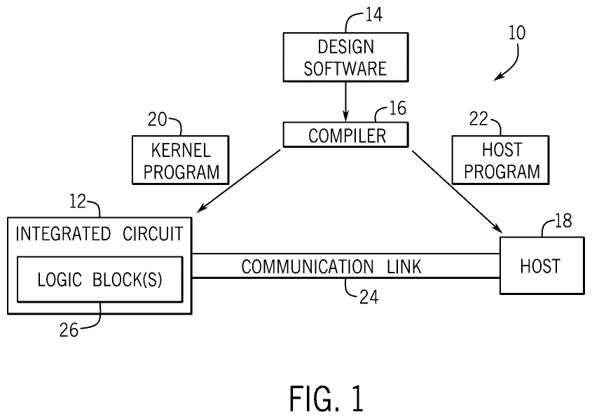

With the foregoing in mind, FIG. 1 illustrates a block diagram of a system 10 that may implement one or more functionalities. For example, a designer may desire to implement functionality, such as the operations of this disclosure, on an integrated circuit device 12 (e.g., a programmable logic device, such as a field programmable gate array (FPGA) or an application specific integrated circuit (ASIC)). In some cases, the designer may specify a high-level program to be implemented, such as an OpenCL® program, which may enable the designer to more efficiently and easily provide programming instructions to configure a set of programmable logic cells for the integrated circuit device 12 without specific knowledge of low-level hardware description languages (e.g., Verilog or VHDL). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

The designer may implement high-level designs using design software 14, such as a version of INTEL® QUARTUS® by INTEL CORPORATION. The design software 14 may use a compiler 16 to convert the high-level program into a lower-level description. In some embodiments, the compiler 16 and the design software 14 may be packaged into a single software application. The compiler 16 may provide machine-readable instructions representative of the high-level program to a host 18 and the integrated circuit device 12. The host 18 may receive a host program 22 which may be implemented by the kernel programs 20. To implement the host program 22, the host 18 may communicate instructions from the host program 22 to the integrated circuit device 12 via a communications link 24, which may be, for example, direct memory access (DMA) communications or peripheral component interconnect express (PCIe) communications. In some embodiments, the kernel programs 20 and the host 18 may enable configuration of a logic block 26 on the integrated circuit device 12. The logic block 26 may include circuitry and/or other logic elements and may be configured to implement arithmetic operations, such as addition and multiplication.

The designer may use the design software 14 to generate and/or to specify a low-level program, such as the low-level hardware description languages described above. For example, the design software 14 may be used to map a workload to one or more routing resources of the integrated circuit device 12 based on a timing, a wire usage, a logic utilization, and/or a routability. In another example, the design software 14 may be used to route first data to a portion of the integrated circuit device 12 and route second data, power, and clock signals to a second portion of the integrated circuit device 12. Further, in some embodiments, the system 10 may be implemented without a separate host program 22. Moreover, in some embodiments, the techniques described herein may be implemented in circuitry as a non-programmable circuit design. Thus, embodiments described herein are intended to be illustrative and not limiting.

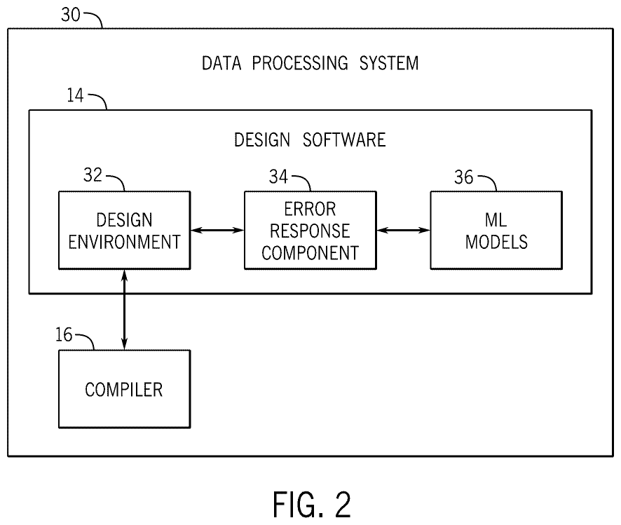

FIG. 2 illustrates a block diagram of a data processing system 30 that may execute instructions of the design software 14 and the compiler 16 to adjust a system design in response to an unsuccessful compilation. In the illustrated example, the design software 14 includes a design environment 32, an error response component 34, and one or more language-based ML models 36. The data processing system 30 may include a suitable memory and/or storage to store the design environment 32, the error response component 34, and/or the one or more language-based ML models 36. In addition, the data processing system 30 may include suitable processing circuitry (e.g., a microprocessor formed in hard logic circuitry or soft logic circuitry) that executes instructions of the design environment 32, the error response component 34, the one or more language-based ML models 36, and/or the compiler 16.

The design environment 32 may include code editors, build automation tools, debuggers, testing tools, project management tools, or other functions that facilitate the development of a system design for an FPGA. The design environment 32 may, upon instruction, use a compiler 16 to convert a high-level program into a lower-level description. In some embodiments, the compiler 16 and the design software 14 may be packaged into a single software application, and/or the compiler 16 may be part of the design software 14. The compiler 16 may provide machine-readable instructions representative of the high-level program to a host and an FPGA.

In some cases, the compiler 16 may be unable to successfully compile a system design developed using the design environment 32. For example, compilation may be unsuccessful due to syntax errors, resource constraints, clocking issues, design rule violations, timing violations, and the like in the system design. In response, the design environment 32 may generate a compilation error message based on, for example, an interval of compilation of the system design at which the compiler 16 ended compilation. The compilation error message may include, for example, a snippet of code of the system design or a portion of a library used to validate the system design (e.g., legality code of an FPGA model).

The compilation error message may be provided, as input, to the error response component 34. Based on the compilation error message, the error response component 34 may generate a language-based ML model prompt. The error response component 34 may then determine an adjustment to the system design based on providing the language-based ML model prompt to the one or more language-based ML models 36. The error response component 34 may then implement the adjustment to the system design, and the design environment 32 may compile the adjusted system design using the compiler 16.

The one or more language-based ML models 36 may include one or more large language models (LLMs), multi-modal generative artificial intelligence (AI) models, or other suitable ML models. Further, while the one or more language-based ML models 36 are illustrated as part of the design software 14, in some examples, the one or more language-based ML models 36 may be stored elsewhere. For example, the one or more language-based ML models 36 may be stored locally on the data processing system 30 and accessible by the design software 14 or, additionally or alternatively, may be stored remotely (e.g., on a remote server) and accessed by the design software 14 by, for example, a wide-area network (WAN) or cloud connection.

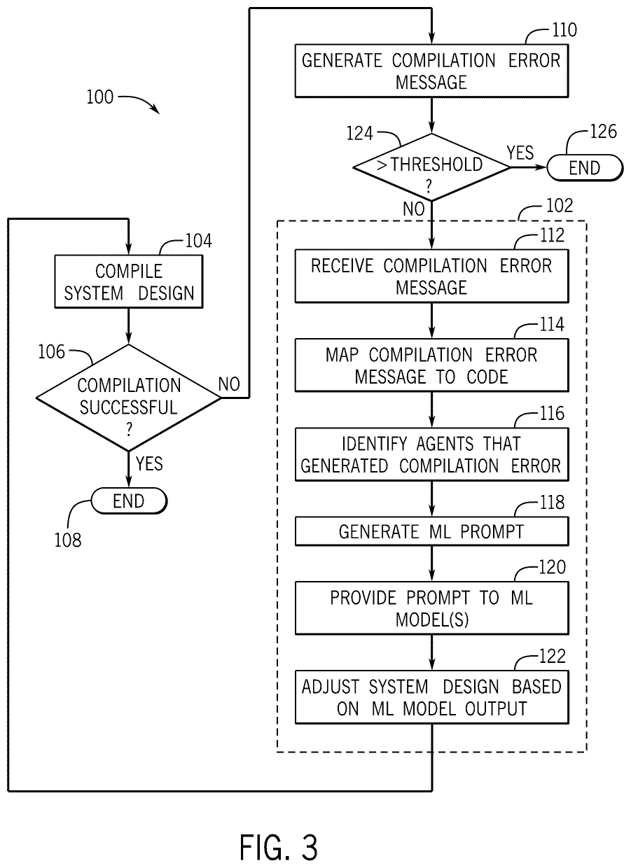

FIG. 3 is a flow chart of a method 100 for adjusting a system design based on one or more language-based ML models in response to a compilation error that may be performed by the data processing system 30. Steps of the method 100 may be performed in any order, and may be performed by the design software 14, including the design environment 32, the error response component 34, and the one or more language-based ML models 36, by the compiler 16, or by other components of the data processing system 30. In one example, the error response component performs an adjustment 102 using the one or more language-based ML models 36, while other components perform other functions of the method 100.

In block 104, the data processing system 30 may attempt to compile the system design. The attempt to compile the system design may initiate based on, for example, instructions received via the design software 14, and may be performed by the compiler 16. For example, the design software 14 may initiate a synthesis or fit function or subroutine that converts the system design from a high-level program to a lower-level description using the compiler 16. If, in block 106, the compilation is successful, the data processing system 30 may transmit the lower-level description of the system design to an FPGA, and may generate an indication of the successful compilation. If, however, the compilation is not successful, the data processing system 30 may generate a compilation error message in block 110. As mentioned, the compilation error message may include, for example, a snippet of code of the system design or a portion of a library used to validate the system design (e.g., legality code of an FPGA model). The compilation error message may include a portion of code at which compilation ended unsuccessfully, for instance.

Moving on to the adjustment 102, the error response component 34 may receive the compilation error message in block 112. The error response component 34 may then, in block 114, map the compilation error message to one or more portions of the design software 14 responsible for producing the compilation error. As mentioned, the design software may include legality code used by the compiler 16 to determine whether a system design would function properly on a device. The legality code may include rules and constraints for resources, connections, timings, and so on of the device. After mapping the compilation error message to the one or more portions of the design software 14 responsible for producing the compilation error, the error response component may determine one or more agents that correspond to the one or more portions. The one or more agents may include subsystems, parameters, commands, or other aspects of a system design that may produce an error. As such, the error response component may determine the one or more agents that may be responsible for generating the compilation error message.

In block 118, the error response component 34 may generate a language-based ML model prompt. As described herein, the language-based ML model prompt may include a code portion of the compilation error message, along with a natural language prompt. The natural language prompt may include one or more agents determined to be responsible for the compilation error message and a natural language indication of a desired output. In some embodiments, the prompt may include the one or more agents as listings of potential agents from which the language-based ML model may select as identified agents. The potential agents may include commands (e.g., add, delete, modify), subsystems and/or values (e.g., port, parameter), identifiers (e.g., port name, parameter name), or other aspects of a system design. The indication of the desired output included in the language-based ML model prompt may take a natural language form.

In block 120, the error response component 34 may provide the language-based ML model prompt to the one or more language-based ML models 36. As mentioned, the one or more language-based ML models 36 may be trained on numerous prior compilation error messages to produce a language-based ML output that addresses the compilation error (e.g., may be fine-tuned to address compilation errors). In some embodiments, the language-based ML output may be arranged in a form readable (e.g., as input) to a script of the design software, and the script may adjust the system design based on the language-based ML output.

In block 122, the error response component 34 may adjust the system design based on the language-based ML output. This may include, for example, executing a script that accepts the language-based ML output as input and adjusts the system design based on the language-based ML output. Adjustments may include changes to parameters, connections, identifiers, or other aspects of the system design. As such, the error response component 34 may automatically adjust the system design without additional input from a designer. Additionally, or alternatively, the error response component 34 may present the adjustment as a recommended change such that a designer can manually approve the change.

The method 100 may then return to block 104, in which the data processing system 30 may attempt to compile the adjusted system design. If, in block 106, the compilation of the adjusted system design is successful, the data processing system 30 may transmit a lower-level description of the adjusted system design to an FPGA, and may generate an indication of the successful compilation. If, however, the compilation is not successful, the data processing system 30 may generate an additional compilation error message in block 110, and the error response component may perform the adjustment 102 again using the one or more language-based ML models 36.

In some examples, the method 100 may repeat, such that the error response component 34 makes multiple iterative adjustments to a system design. Further, in some cases, the error response component 34 may continue to perform adjustments until a threshold number of adjustments have been made and/or a threshold number of compilations has been performed. For example, after generating the compilation error message in block 110, the data processing system may determine whether the adjustment threshold has been reached in block 124. If the adjustment threshold has been reached, in block 126, the adjustment 102 may not be performed, and the data processing system 30 may generate an indication that the adjustment threshold has been reached. If, however, the adjustment threshold has not been reached, the error response component 34 may perform the adjustment 102.

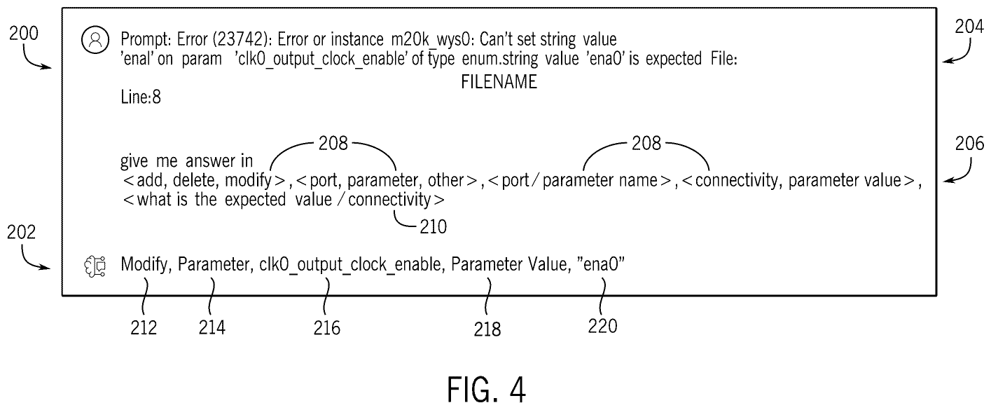

FIG. 4 illustrates an example of a language-based ML model prompt 200 that may be generated by the error response component 34 as well as an example of a language-based ML output 202 that may be determined by the error response component 34 based on the one or more language-based ML models 36. As illustrated, the language-based ML model prompt 200 may include a code portion 204 of the compilation error message, along with a natural language prompt 206. The code portion 204 may include, for example, a portion of compiler code or legality code that threw an error during compilation, for instance. The natural language prompt 206 may include one or more agents 208 determined to be responsible (e.g., potentially responsible) for the compilation error message and a natural language indication 210 of a desired output. As illustrated, the prompt may include the one or more agents 208 as listings of potential agents that the one or more language-based ML models 36 may generate the language-based ML output 202 based on. For example, the one or more agents may include “add, delete, modify”, “port, parameter, others”, and so on, which may indicate commands (e.g., add, delete, modify), subsystems and/or values (e.g., port, parameter), identifiers (e.g., port name, parameter name), or other aspects of a system design. Further, the natural language indication 210 of the desired output may indicate a query related to a subsystem of the system design, and the language-based ML output 202 may include an answer to the query.

As illustrated, the language-based ML output 202 may indicate aspects of the system design and adjustments that may be made to resolve an unsuccessful compilation. In the illustrated example, the language-based ML output 202 includes a command 212, a subsystem 214, an identifier 216 of the subsystem, a variable 218, and an adjustment 220. In some cases, the aspects identified in the language-based ML output 202 may include the one or more agents 208. For example, the command 212 and the subsystem 214 were “selected” from listings of the one or more agents 208. In other cases, the language-based ML output 202 includes aspects that are not part of the language-based ML model prompt 200 (e.g., the identifier 216 and the adjustment 220). That is, the one or more language-based ML models 36 may be used to generate aspects and adjustments that were not found by the error response component 34.

As described herein, the language-based ML output 202 may be arranged in a form readable (e.g., as input) to a script of the design software, and the script may adjust the system design based on the language-based ML output 202. In the illustrated example, a script may modify (e.g., based on the command 212) a parameter (e.g., based on the subsystem 214) identified as “clk0_output_clock_enable” (e.g., based on the identifier 216). The script may change a parameter value (e.g., based on the variable 218) by changing the parameter value to “ena0” (e.g., based on the adjustment 220). As may be appreciated, the language-based ML model prompt 200 may take various forms based on qualities of the one or more language-based ML models 36, and the language-based ML output 202 may take various forms to be readable by a script of the error response component 34.

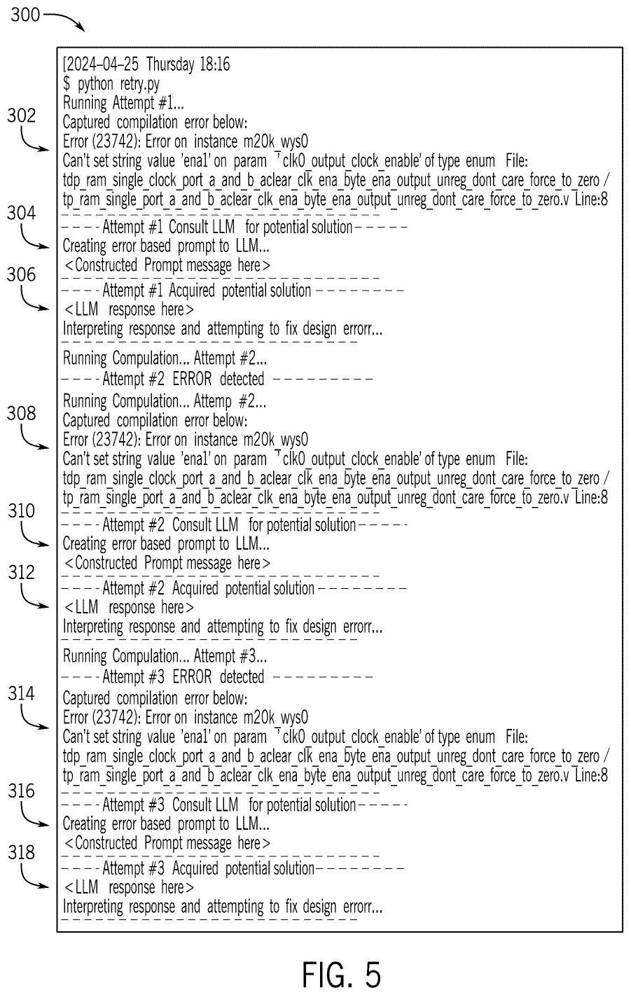

FIG. 5 illustrates an example user interface 300 that may be display by the data processing system 30 when adjusting a system design according to the method 100 of FIG. 3. As illustrated, the example user interface 300 may display a first compilation error message 302 in response to an unsuccessful compilation attempt of a system design. The example user interface 300 may then display an indication 304 that a first language-based ML model prompt is being created and an indication 306 that a first adjustment has been determined based on the one or more language-based ML models 36. The adjustment may then be implemented by the error response component 34 to generate an adjusted system design.

The example user interface 300 may then update to include a second compilation error message 308 in response to an unsuccessful compilation attempt of the adjusted system design. The example user interface 300 may then display as second indication 310 that a second language-based ML model prompt is being created and an indication 312 that a second adjustment has been determined based on the one or more language-based ML models 36. The adjustment may then be implemented by the error response component 34 to generate a twice-adjusted system design.

The example user interface 300 may then update to include a third compilation error message 314 in response to an unsuccessful compilation attempt of the twice-adjusted system design. The example user interface 300 may then display as third indication 316 that a third language-based ML model prompt is being created and an indication 318 that a third adjustment has been determined based on the one or more language-based ML models 36. The adjustment may then be implemented by the error response component 34 to generate a thrice-adjusted system design. As described herein, the method 100 may be repeated until a compilation is successfully completed or a threshold number of adjustments is reached, and the example user interface 300 may continue to update accordingly.

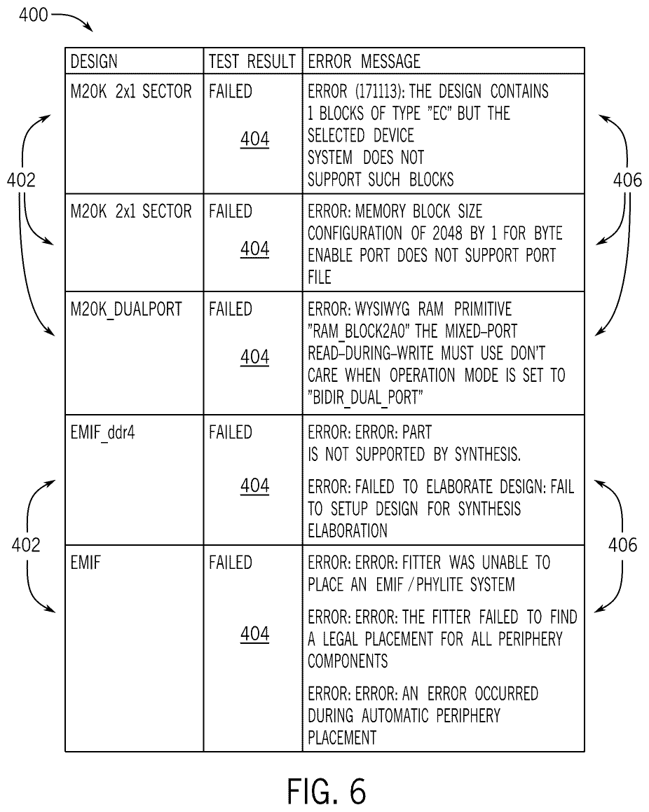

FIG. 6 is an illustration of example training data 400 that may be provided to train the one or more language-based ML models 36. The example training data 400 may include information from prior compilation attempts including error messages of prior system designs.

As illustrated, the example training data 400 may include device information 402, such as specifications or identifiers of FPGA models and the like of device used during prior compilation attempts. The device information 402 may provide an indication of connections, subsystems, or other aspects specific to devices that may consume different resources, have different connections, produce different errors during compilation, and so on. The example training data 400 also includes test results 404, which may indicate whether prior compilations of system designs were successful or unsuccessful. Additionally, the example training data 400 includes error messages 406 (e.g., compilation error messages) of prior system designs that indicate one or more errors that occurred during prior compilations of system designs (e.g., prior system designs, other system designs). As described herein, the prior system designs may or may not have a direct relationship to the system design of the compilation error message received by the error response component. For example, the error messages 406 of the prior system designs may be from actual system designs developed by a first-party manufacturer of the FPGA, a first-party manufacturer of the design software, or a third-party developer different from the first party-manufacturer of the design software. Additionally or alternatively, the error messages 406 may include synthetic data from arbitrary system design code generated for training purposes, such as system design code produced by machine learning systems such as the one or more language-based ML models.

While the example training data 400 is shown for illustrative purposes, other data may be included in training data used to train the one or more language-based ML models 36. In some examples, the training data may include prior adjustments made in response to prior compilation errors, indications of whether the adjustments successfully resolved the compilation errors, and so on. Further, in some cases, training data may be iteratively provided to the one or more language-based ML models 36. For example, if an adjustment is implemented to generate an adjusted system design, the adjustment, as well as an indication of whether the adjustment was successful or unsuccessful, may be used to train the one or more language-based ML models 36. Updated training data may be provided to the one or more language-based ML models 36 at every repetition of the method 100 while adjustments to a system design are being made, for instance. The training data may also include identified solutions to compilation errors. The identified solutions may be verified as successful adjustments to prior compilation errors, for instance.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. A method, comprising: receiving an error message associated with a system design of a field-programmable gate array (FPGA); generating a language-based machine learning (ML) prompt based at least on the error message; and determining an adjustment to the system design based on providing the language-based ML prompt to one or more language-based ML models trained on error messages of prior system designs.
EXAMPLE EMBODIMENT 2. The method of example embodiment 1, wherein the error message is generated based on compiler software, and comprising: identifying one or more subsystems of the compiler software associated with the error message, wherein the language-based machine learning (ML) prompt indicates the one or more subsystems.
EXAMPLE EMBODIMENT 3. The method of example embodiment 1, comprising: applying the adjustment to the system design of the FPGA to generate an adjusted system design; receiving a compilation result of the adjusted system design; and providing the adjustment and the compilation result to the one or more language-based ML models as training data.
EXAMPLE EMBODIMENT 4. The method of example embodiment 1, wherein the one or more language-based ML models are trained on identified solutions to the error messages of the prior system designs.
EXAMPLE EMBODIMENT 5. The method of example embodiment 1, wherein the one or more language-based ML models produce a script output.
EXAMPLE EMBODIMENT 6. The method of example embodiment 5, implementing the adjustment to the system design according to the script to generate an adjusted system design.
EXAMPLE EMBODIMENT 7. The method of example embodiment 6, comprising compiling the adjusted system design.
EXAMPLE EMBODIMENT 8. A system, comprising: one or more language-based machine learning (ML) models trained on error messages of prior system designs; and a data processing system comprising: an error response component to run on the data processing system to: receive an error message associated with a system design of a field-programmable gate array (FPGA); generate a language-based machine learning (ML) prompt based at least on the error message; and determine an adjustment to the system design based on providing the language-based ML prompt to the one or more language-based ML models;
EXAMPLE EMBODIMENT 9. The system of example embodiment 8, comprising the FPGA, the FPGA communicatively coupled to the data processing system.
EXAMPLE EMBODIMENT 10. The system of example embodiment 8, wherein the one or more language-based ML models comprise a large language model (LLM)
EXAMPLE EMBODIMENT 11. The system of example embodiment 8, wherein the one or more language-based ML models are local to the data processing system.
EXAMPLE EMBODIMENT 12. The system of example embodiment 8, wherein the one or more language-based ML models are remote to the data processing system,
EXAMPLE EMBODIMENT 13. The system of example embodiment 8, wherein the error message indicates a code portion, and wherein the language-based machine learning (ML) prompt comprises: the code portion indicated in the error message; and a natural language prompt indicating one or more aspects of the system design.
EXAMPLE EMBODIMENT 14. The system of example embodiment 13, wherein the natural language prompt specifies an indication of a desired output of the one or more language-based ML models.
EXAMPLE EMBODIMENT 15. The system of example embodiment 8, wherein the one or more language-based ML models provide an output in response to the language-based ML prompt as a script.
EXAMPLE EMBODIMENT 16. The system of example embodiment 15, wherein the script is readable by the data processing system and, when executed by the data processing system, causes the data processing system to adjust the system design.
EXAMPLE EMBODIMENT 17. A tangible, non-transitory, and computer-readable medium, storing instructions thereon, wherein the instructions, when executed, are to cause a processor to: receive an error message associated with a system design of a field-programmable gate array (FPGA); generate a language-based machine learning (ML) prompt based at least on the error message; and determine an adjustment to the system design based on providing the language-based ML prompt to one or more language-based ML models trained on error messages of prior system designs.
EXAMPLE EMBODIMENT 18. The tangible, non-transitory, and computer-readable medium of example embodiment 17, wherein the error message comprises a compilation error message generated in response to a compilation attempt of the system design.
EXAMPLE EMBODIMENT 19. The tangible, non-transitory, and computer-readable medium of example embodiment 17, wherein the one or more language-based ML models are trained on identified solutions to the error messages of the prior system designs.
EXAMPLE EMBODIMENT 20. The tangible, non-transitory, and computer-readable medium of example embodiment 17, wherein the language-based ML prompt comprises an indication of one or more parameters or subsystems of the system design.

What is claimed is:

1. A method, comprising:
receiving an error message associated with a system design of a field-programmable gate array (FPGA);
generating a language-based machine learning (ML) prompt based at least on the error message; and
determining an adjustment to the system design based on providing the language-based ML prompt to one or more language-based ML models trained on error messages of prior system designs.

2. The method of claim 1, wherein the error message is generated based on compiler software, and comprising:
identifying one or more subsystems of the compiler software associated with the error message, wherein the language-based machine learning (ML) prompt indicates the one or more subsystems.

3. The method of claim 1, comprising:
applying the adjustment to the system design of the FPGA to generate an adjusted system design;
receiving a compilation result of the adjusted system design; and
providing the adjustment and the compilation result to the one or more language-based ML models as training data.

4. The method of claim 1, wherein the one or more language-based ML models are trained on identified solutions to the error messages of the prior system designs.

5. The method of claim 1, wherein the one or more language-based ML models produce a script output.

6. The method of claim 5, implementing the adjustment to the system design according to the script to generate an adjusted system design.

7. The method of claim 6, comprising compiling the adjusted system design.

8. A system, comprising:
one or more language-based machine learning (ML) models trained on error messages of prior system designs; and
a data processing system comprising:
an error response component to run on the data processing system to:
receive an error message associated with a system design of a field-programmable gate array (FPGA); and
generate a language-based machine learning (ML) prompt for the one or more language-based machine learning (ML) models based at least on the error message.

9. The system of claim 8, wherein the one or more language-based ML models comprise a large language model (LLM).

10. The system of claim 8, wherein the one or more language-based ML models are local to the data processing system.

11. The system of claim 8, wherein the one or more language-based ML models are remote to the data processing system.

12. The system of claim 8, wherein the error message indicates a code portion, and wherein the language-based machine learning (ML) prompt comprises:
the code portion indicated in the error message; and
a natural language prompt indicating one or more aspects of the system design.

13. The system of claim 12, wherein the natural language prompt specifies an indication of a desired output of the one or more language-based ML models.

14. The system of claim 8, wherein the one or more language-based ML models provide an output in response to the language-based ML prompt as a script.

15. The system of claim 14, wherein the script is readable by the data processing system and, when executed by the data processing system, causes the data processing system to adjust the system design.

16. The system of claim 8, comprising the FPGA, the FPGA communicatively coupled to the data processing system.

17. A tangible, non-transitory, and computer-readable medium, storing instructions thereon, wherein the instructions, when executed, are to cause a processor to:
receive an error message associated with a system design of a field-programmable gate array (FPGA);
generate a language-based machine learning (ML) prompt based at least on the error message; and
determine an adjustment to the system design based on providing the language-based ML prompt to one or more language-based ML models trained on error messages of prior system designs.

18. The tangible, non-transitory, and computer-readable medium of claim 17, wherein the error message comprises a compilation error message generated in response to a compilation attempt of the system design.

19. The tangible, non-transitory, and computer-readable medium of claim 17, wherein the one or more language-based ML models are trained on identified solutions to the error messages of the prior system designs.

20. The tangible, non-transitory, and computer-readable medium of claim 17, wherein the language-based ML prompt comprises an indication of one or more parameters or subsystems of the system design.
